(19) United States
(12) Patent Application Publication
(10) Pub. No.: US 2026/0341333 A1
(43) Pub. Date: Oct. 29, 2026

(54) MEMORY DEVICES, OPERATING METHODS THEREOF, AND MEMORY SYSTEMS

(71) Applicant: Yangtze Memory Technologies Co., Ltd., Wuhan (CN)

(72) Inventors: Sinan Yang, Wuhan (CN); Zhaohong Li, Wuhan (CN); Guanyu Sha, Wuhan (CN); Xiang Fu, Wuhan (CN); Yu Wang, Wuhan (CN); ZhiChao Du, Wuhan (CN)

(21) Appl. No.: 19/338,851

(22) Filed: Sep. 24, 2025

(30) Foreign Application Priority Data
Apr. 28, 2025 (CN) 202510548808.1

(51) Int. Cl. G11C 11/4074; G11C 11/408; G11C 11/4091; G11C 11/4094

(52) U.S. Cl. CPC G11C 11/4074; G11C 11/4085; G11C 11/4091; G11C 11/4094

(57) ABSTRACT

An example memory device comprises: a memory cell, a power-on initialization circuit, and first and second driving circuits, the memory cell comprises a capacitor and a transistor, the transistor is coupled to a first terminal of the capacitor, the power-on initialization circuit is coupled to the memory cell and is configured to perform power-on initialization on the memory cell based on the memory device being powered on, the first driving circuit is coupled to the power-on initialization circuit and a second terminal of the capacitor, respectively, and is configured to apply a first driving voltage to the second terminal during a power-on initialization phase, the second driving circuit is coupled to the power-on initialization circuit and a word line, respectively, and is configured to apply a second driving voltage to the word line during the power-on initialization phase to turn on the transistor coupled to the word line.

### CROSS-REFERENCE TO RELATED APPLICATION

This application claims priority to and the benefit of Chinese Patent Application 202510548808.1, filed on Apr. 28, 2025, which is hereby incorporated by reference in its entirety.

### TECHNICAL FIELD

Examples of the present disclosure relate to the field of semiconductor technologies, and relate to, but are not limited to, memory devices, operating methods thereof, and memory systems.

### BACKGROUND

A memory device is divided into a volatile memory and a non-volatile memory, depending on whether stored data is retained during power failure. Volatile memory in which data is lost during power failure may comprise a static random access memory (SRAM) and a dynamic random access memory (DRAM).

### BRIEF DESCRIPTION OF DRAWINGS

In the drawings, like reference numbers refer to like or similar parts or elements throughout the several drawings unless otherwise specified. These drawings are not necessarily drawn to scale. It should be understood that these drawings depict only some examples disclosed in accordance with the present disclosure and should not be considered as limiting the scope of the present disclosure.

FIG. 1 is a schematic diagram of a system according to an example of the present disclosure.

FIG. 2A and FIG. 2B are schematic diagrams of a memory device according to an example of the present disclosure.

FIG. 3A is a schematic diagram of a power-on initialization circuit according to an example of the present disclosure.

FIG. 3B is a timing diagram of a power-on initialization according to an example of the present disclosure.

FIG. 4A is a schematic diagram of applying a voltage to a memory cell according to an example of the present disclosure.

FIG. 4B is a schematic diagram of a peripheral circuit according to an example of the present disclosure.

FIG. 4C is a timing diagram of applying a voltage to a memory cell according to an example of the present disclosure.

FIG. 5 is a schematic diagram of another memory device according to an example of the present disclosure.

FIG. 6A is a schematic diagram of a peripheral circuit according to a first example of the present disclosure.

FIG. 6B is a timing diagram of applying a second driving voltage to a word line according to a first example of the present disclosure.

FIG. 7A is a schematic diagram of a peripheral circuit according to a second example of the present disclosure.

FIG. 7B is a timing diagram of applying a second driving voltage to a word line according to a second example of the present disclosure.

FIG. 8A is a schematic diagram of a peripheral circuit according to a third example of the present disclosure.

FIG. 8B is a timing diagram of applying a second driving voltage to a word line according to a third example of the present disclosure.

FIG. 9 is a schematic flowchart of an operating method of a memory device according to an example of the present disclosure.

### DETAILED DESCRIPTION

For ease of understanding of the present disclosure, example examples disclosed in the present disclosure will be described in more detail below with reference to the accompanying drawings. Although example examples of the present disclosure are shown in the accompanying drawings, it should be understood that the present disclosure may be implemented in various forms and should not be limited to the example examples set forth herein. Rather, these examples are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In some examples, in order to avoid confusion with the present disclosure, some technical features known in the art are not described; that is, not all features of the actual example may be described here, and well-known functions and structures are not described in detail.

In general, the terms may be understood at least in part from the use in the context. For example, depending at least in part on context, the term “one or more” as used herein may be used to describe any feature, structure, or characteristic in a singular sense, or may be used to describe a combination of features, structures, or characteristics in a plural sense. Similarly, terms such as “a” or “the” may likewise be understood to convey singular usage or convey complex usage, depending at least in part on context. In addition, the term “based on” may be understood to not necessarily be intended to convey an exclusive set of factors, and may instead allow for the presence of additional factors that are not necessarily explicitly described, again depending at least in part on the context.

Unless otherwise defined, terms used herein are for the purpose of describing a particular example only and are not to be considered as limiting the present disclosure. As used herein, the singular forms “a”, “an” and “said/the” are intended to comprise the plural forms as well, unless the context clearly dictates otherwise. It should also be understood that the terms “consists of” and/or “comprising”, when used in this description, identify the presence of stated features, integers, steps, operations, elements and/or parts, but do not exclude the presence or addition of one or more other features, integers, steps, operations, elements, parts and/or groups. As used herein, the term “and/or” comprises any and all combinations of associated listed items.

For a thorough understanding of the present disclosure, detailed steps and detailed structures will be presented in the following description in order to set forth technical solutions of the present disclosure. Preferred examples of the present disclosure are described in detail below, however, other examples may be provided in addition to these detailed descriptions.

After being powered on, dynamic random access memory (DRAM) usually needs to perform a series of power-on initialization steps, for example, setting an operating voltage, a timing parameter, starting a refresh mechanism, etc., to ensure normal operations of the DRAM. However, power-on initialization may cause memory cells to be in an undetermined state, affecting reliability of a subsequent data read.

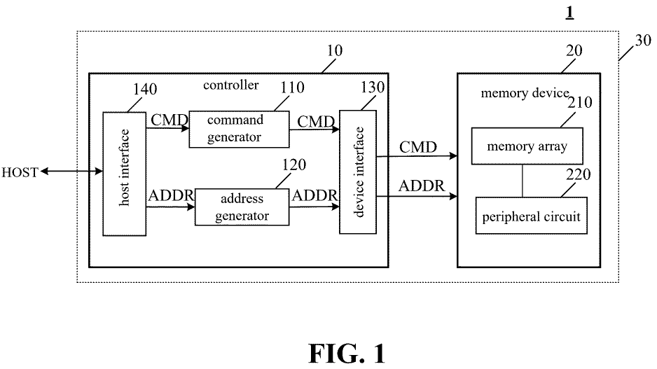

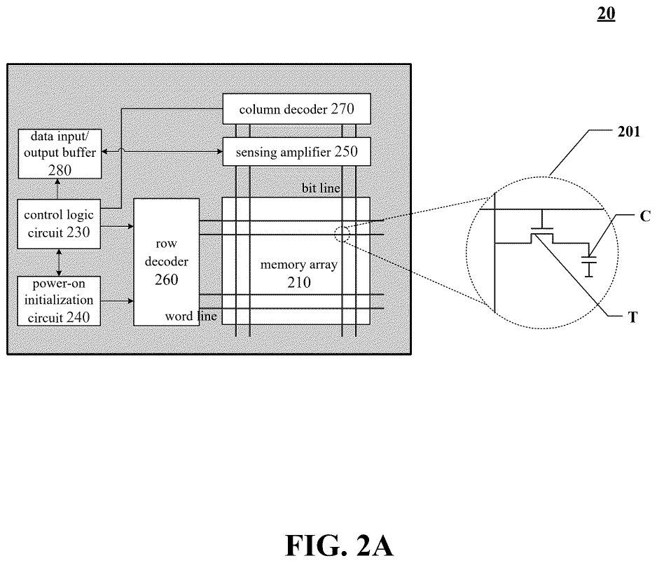

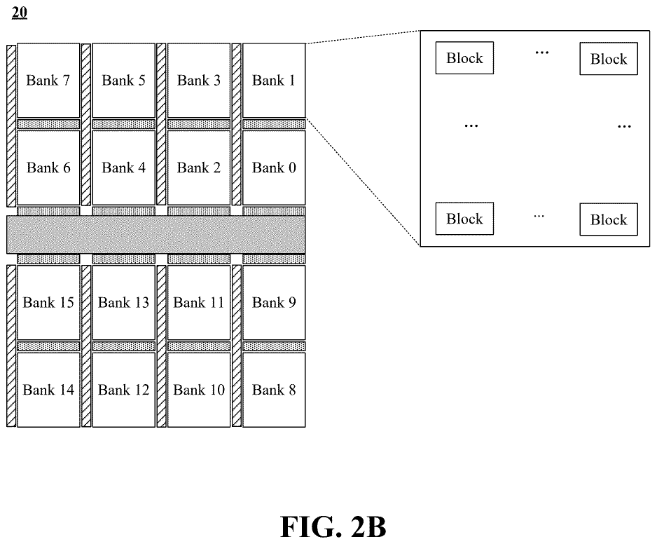

FIG. 1 is a schematic diagram of a system according to an example of the present disclosure, and FIG. 2A and FIG. 2B are schematic diagrams of a memory device according to an example of the present disclosure.

Referring to FIG. 1, the system 1 may comprise a host HOST and a memory system 30. In an example of the present disclosure, the system 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device therein.

The host HOST may be a processor (for example, a central processing unit (CPU) or a system on chip (SoC) (for example, an application processor (AP)) of the electronic device. The memory system 30 has one or more memory devices 20 and a controller 10. The host HOST may be configured to send or receive data to or from the memory device 20. The controller 10 is coupled to the memory device 20 and the host HOST, respectively, and is configured to control the memory device 20. The controller 10 may manage data stored in the memory device 20 and communicate with the host HOST.

The controller 10 may be configured to control operations of the memory device 20, such as read, write, and refresh operations. In some examples, the controller 10 is further configured to process error correction codes (ECCs) regarding data read from or written to the memory device 20. The controller 10 may also perform any other suitable functions, such as formatting the memory device 20.

In some examples, the controller 10 and the one or more memory devices 20 may be integrated into various types of storage devices, for example, the controller 10 may be integrated into a northbridge of a computer motherboard or integrated directly into a computer CPU, and multiple memory devices 20 may be integrated into a memory bank. That is, the memory system 30 may be implemented and packaged into different types of terminal electronics.

The controller 10 may send data to or receive data from the host HOST, and may send a command CMD and an address ADDR to the memory device 20. The controller 10 may comprise a command generator 110, an address generator 120, a device interface 130, and a host interface 140. The host interface 140 may receive the command CMD and the address ADDR from the host HOST, the command generator 110 may generate an access command, a refresh command, and the like by decoding the command CMD received from the host HOST, and may provide the access command and the refresh command to the memory device 20 through the device interface 130. The access command may be a signal instructing the memory device 20 to write or read data by accessing a row of a memory array 210 corresponding to the address ADDR. The refresh command may instruct the memory array 210 of the memory device 20 to perform a refresh operation of stored data.

The address generator 120 in controller 10 may generate row addresses and column addresses to be accessed in the memory array 210 by decoding the address ADDR received from host interface 140. Further, the memory device 20 may generate addresses of banks to be accessed when the memory array 210 comprises multiple banks.

Further, the controller 10 may control operations, such as writing and reading, of the memory device by providing various signals to the memory device 20 via the device interface 130. For example, the controller 10 may provide a write command to the memory device 20. The write command is configured to instruct the memory device 20 to perform a write operation to store data into the memory device 20. The memory device 20 may be a random access memory (RAM), such as dynamic random access memory (DRAM), synchronous DRAM (SDRAM), double data rate SDRAM (DDR SDRAM), DDR2 SDRAM, DDR3 SDRAM, phase-change RAM (PRAM), magnetic RAM (MRAM), resistive RAM (RRAM), or the like.

Referring to FIGS. 1, 2A, and 2B, the memory device 20 comprises a memory array 210 and a peripheral circuit 220. The memory array 210 comprises a plurality of memory banks, and as an example, FIG. 2B shows 16 memory banks, e.g., Bank0 to Bank15. Each memory bank comprises a plurality of memory blocks, each memory block comprises a plurality of memory cell rows and a plurality of memory cell columns, each memory cell row is coupled to a corresponding one of the word lines, and each memory cell column is coupled to a corresponding one of the bit lines.

The peripheral circuit 220 may comprise a control logic circuit 230, which may be coupled to the various circuits described below and configured to control operations of the various circuits. As an example, the control logic circuit 230 may generate a corresponding control signal based on a command issued by the controller 10, and send the control signal to a corresponding circuit.

The peripheral circuit 220 may further comprise a power-on initialization circuit 240 coupled to the memory array 210, and the power-on initialization circuit 240 may perform power-on initialization on the memory array 210 in a case that the memory device is powered on, to initialize each memory cell 201. After the power-on initialization is completed, operations such as read, write, or refresh may be performed on a selected memory cell 201.

The peripheral circuit 220 may further comprise a control circuit corresponding to each memory block, for example, a sensing amplifier (SA) 250 and a word-line driver (WLD), etc., a control circuit corresponding to each memory bank, for example, a row decoder 260, a column decoder 270, and the like, and a control circuit corresponding to all memory banks, for example, a data input/output buffer 280, a command buffer, a command decoder, an address buffer, a mode register, and the like.

The peripheral circuit 220 may write data to or read data from memory array 210 based on commands CMD and addresses ADDR received from controller 10, or may provide, to the row decoder 260 and the column decoder 270, control signals CTRLs for refreshing memory cells comprised in memory array 210. In other words, the peripheral circuit 220 may perform all operations to process data in the memory array 210.

Referring to FIG. 2A, the memory device comprises at least one DRAM die, each DRAM die comprises a memory array 210, the memory array 210 comprises a plurality of memory cells 201 arranged in an array, and each memory cell 201 comprises a transistor T and a capacitor C. The main principle of the memory cell is to use the amount of charge stored in the capacitor to represent whether a binary bit is 1 or 0. The memory cells are arranged in an array, which can be regarded as a typical network structure, and the memory array uses a row and a column to specify an address. By specifying the intersection of a row and a column (by specifying a row address and a column address of DRAM), the controller may independently access each memory cell in a DRAM die and perform read, write, or refresh operation on data stored therein.

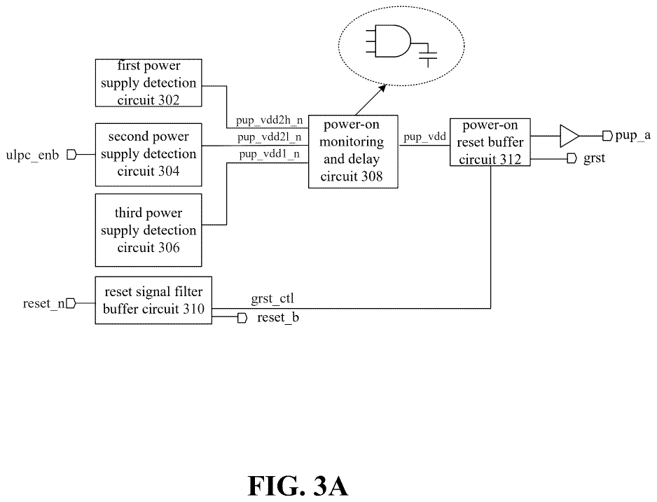

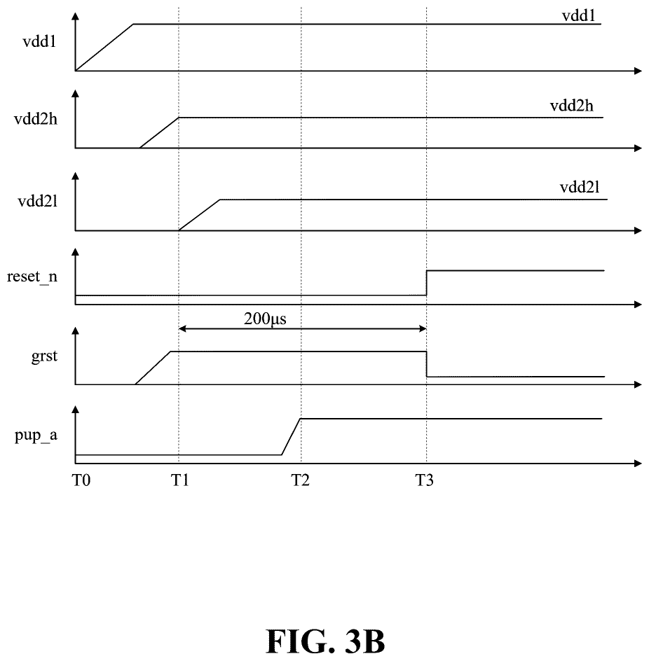

FIG. 3A is a schematic diagram of a power-on initialization circuit according to an example of the present disclosure, FIG. 3B is a timing diagram of power-on initialization according to an example of the present disclosure, and the power-on initialization of a memory device is described by way of example below with reference to FIGS. 3A and 3B.

The power-on initialization circuit comprises at least one power supply detection circuit configured to: detect a power supply voltage based on the memory device being powered on, and output a detection signal. The detection signal indicates whether the power supply voltage reaches a stable state.

As an example, FIG. 3A shows a first power supply detection circuit 302, a second power supply detection circuit 304, and a third power supply detection circuit 306. When the memory device starts to be powered on, the first power supply detection circuit 302, the second power supply detection circuit 304, and the third power supply detection circuit 306 detect a first power supply voltage vdd2h, a second power supply voltage vdd2l, and a third power supply voltage vdd1, respectively, and output a first detection signal pup_vdd2h_n, a second detection signal pup_vdd2l_n, and a third detection signal pup_vdd1_n, respectively. The first detection signal pup_vdd2h_n indicates whether the first power supply voltage vdd2h reaches a stable state, the second detection signal pup_vdd2l_n indicates whether the second power supply voltage vdd2l reaches a stable state, and the third detection signal pup_vdd1_n indicates whether the third power supply voltage vdd1 reaches a stable state.

As an example, FIG. 3B shows that the first power supply voltage vdd2h reaches a stable state at the time T1, the third power supply voltage vdd1 reaches a stable state before the time T1, and the second power supply voltage vdd2l reaches a stable state after the time T1, that is, instances of time at which different power supply voltages reach the stable state are different.

It should be noted that there are usually three sets of power supply voltages inside the DDR, which are vdd1, vdd2 and vddQ, respectively, wherein vdd2 is also divided into vdd2h and vdd2l. Vdd2h is a high-level voltage, which is commonly used in a high-speed operation mode, and vdd2l is a low-level voltage, which is commonly used in a low-speed operation mode. For example, when the ulpc_enb pin in FIG. 3A is activated, the DRAM die uses the low-speed operation mode. In practical applications, the number of the power supply detection circuits is not limited to that shown in FIG. 3A, and may also be other numbers to detect different types of power supply voltages.

The power-on initialization circuit further comprises a power-on monitoring and delay circuit 308 coupled to the power supply detection circuit and configured to delay each received detection signal and output a monitoring signal pup_vdd.

As an example, each input terminal of the power-on monitoring and delay circuit 308 receives a corresponding detection signal, and performs delay processing on the detection signal received by each input terminal until a corresponding power supply voltage (for example, vdd2h, vdd2l, or vdd1) reaches a stable state. Here, by introducing a certain delay, the initialization failure due to the fact that the corresponding power supply voltage has not been completely stabilized can be avoided.

As an example, as shown in FIG. 3B, the power-on monitoring and delay circuit 308 may output the monitoring signal pup_vdd when the first power supply voltage vdd2h reaches a stable state.

The power-on initialization circuit further comprises a reset signal filter buffer circuit 310 coupled to a reset pin and configured to filter a reset signal reset_n received by the reset pin to generate a global reset control signal grst_ctl. Here, the reset signal filter buffer circuit 310 may start to receive the reset signal reset_n when the reset control signal reset_b is at a low level.

As an example, referring to FIG. 3B, at the time T0, the reset signal reset_n is at a low level, after the first power supply voltage vdd2h reaches the stable state (e.g., the time T1), the reset operation is started, and the reset signal reset_n is at least kept for about 200 microseconds (μs), and at the time T3, the reset signal reset_n is switched to a high level, and the DRAM exits the reset state. In this example, the reset signal reset_n is a low level effective signal.

The power-on initialization circuit further comprises a power-on reset buffer circuit 312 coupled to the power-on monitoring and delay circuit 308 and the reset signal filter buffer circuit 310, respectively, and configured to generate a global reset signal grst based on the monitoring signal pup_vdd and the global reset control signal grst_ctl. The global reset signal grst is configured to instruct the memory device to perform a reset operation. After the power-on initialization is completed, a power-on completion signal pup_a is output, and the power-on completion signal pup_a indicates that the memory device has completed power-on.

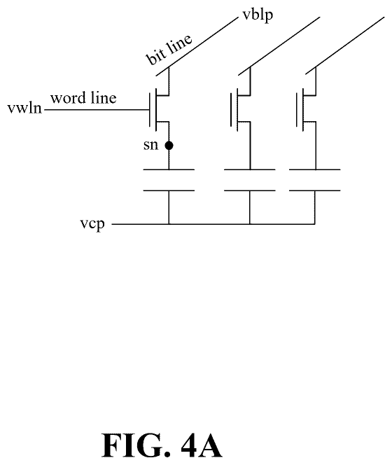

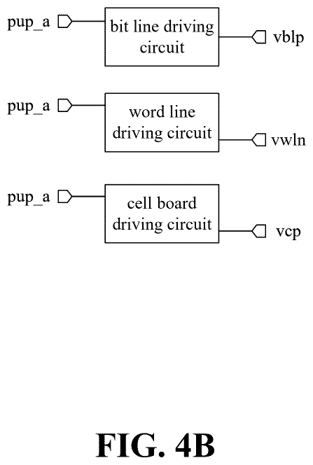

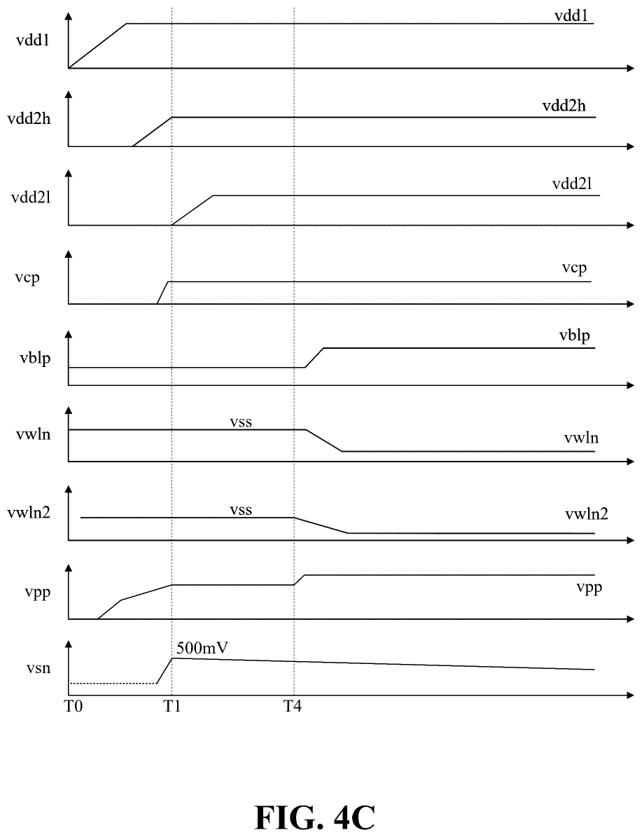

As an example, referring to FIG. 3B, at the time T1 to T3, the global reset signal grst is at a high level, and the memory device performs a reset operation. At time T2, the memory device has completed the power-on and generates the power-on completion signal pup_a. After the power-on is completed, for example, after the time T3, operations such as write, read, and refresh may be performed. However, after the DRAM has completed the power-on, the memory cell may be in an undetermined state, affecting reliability of subsequent data read, which will be described below with reference to FIG. 4A to FIG. 4C.

FIG. 4A is a schematic diagram of applying a voltage to a memory cell according to an example of the present disclosure, FIG. 4B is a schematic diagram of a peripheral circuit according to an example of the present disclosure, and FIG. 4C is a timing diagram of applying a voltage to a memory cell according to an example of the present disclosure.

Referring to FIG. 4A, the memory cell comprises a capacitor and a transistor. As an example, the capacitor comprises a first electrode plate, a second electrode plate, and a dielectric between the first electrode plate and the second electrode plate, the first electrode plate is coupled to the transistor, and the second electrode plate is coupled to a cell board. The second electrode plates of the plurality of capacitors may share the cell board, e.g., the second electrode plates of the plurality of capacitors are each coupled to the cell board.

Referring to FIG. 4A to FIG. 4C, in a power-on initialization phase, a cell board driving circuit may apply a driving voltage vcp to the cell board to initialize all memory cells, after power-on is completed (for example, at the time T4), a bit line driving circuit may apply a bit line driving voltage vblp to a bit line, a word line driving circuit may apply a word line driving voltage vwln to a word line, and by selecting a corresponding bit line and word line, a corresponding memory cell may be selected, and operations such as write, read, or refresh are performed on the selected memory cell.

However, in the power-on initialization phase, the ramp-up of the driving voltage vcp couples memory nodes sn of all memory cells to an undetermined voltage level, e.g., a memory node sn in FIG. 4C is coupled to 500 millivolts (mV). Within the first refresh cycle after power-on initialization, the undetermined voltage level on the memory node sn causes the cell board to have unbalanced current, which increases the voltage level of the cell board, and the higher voltage on the cell board will reduce for example the sensing margin between data “0” and “1”, thereby reducing reliability of data read. Here, vsn in FIG. 4C represents the voltage of the memory node sn, and the memory node sn may be any node between the transistor and the first electrode plate.

Based on one or more of the foregoing technical problems, an example of the present disclosure provides a memory device.

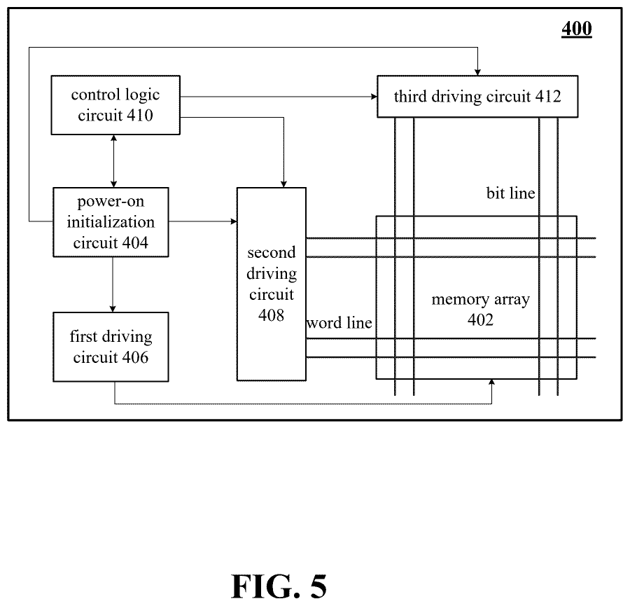

FIG. 5 is a schematic diagram of another memory device according to an example of the present disclosure. The memory device comprises, but is not limited to, DRAM, and for ease of understanding, the following will take the DRAM as an example to illustrate.

Referring to FIGS. 2A, 4A and 5, the memory device 400 comprises a memory array 402 comprising a plurality of memory cells each comprising a capacitor and a transistor, wherein the transistor is coupled to a first terminal of the capacitor. As an example, the first terminal of the capacitor may be a first electrode plate, and the source of the transistor is coupled to the first electrode plate. For specific structures of the memory array 402 and the memory cell, refer to related descriptions of FIG. 2A and FIG. 4A, and details are not described herein again.

The memory device 400 further comprises a power-on initialization circuit 404 coupled to the memory cell and configured to perform power-on initialization on the memory cell based on the memory device 400 being powered on, and for the process regarding the power-on initialization, refer to related descriptions of FIG. 3A and FIG. 3B.

The memory device 400 further comprises a first driving circuit 406 coupled to the power-on initialization circuit 404 and a second terminal of the capacitor, respectively, and configured to apply a first driving voltage to the second terminal in the power-on initialization phase, wherein the first driving voltage is denoted as vcp below.

As an example, the second terminal of the capacitor may be a second electrode plate, and in the power-on initialization phase, the first driving circuit 406 may apply the first driving voltage vcp to the second electrode plate. In this example, the first driving circuit 406 may be the cell board driving circuit shown in FIG. 4B, so as to reuse the cell board driving circuit. Of course, in other examples, the first driving circuit 406 may also be a newly added driving circuit.

The first driving voltage vcp is usually set to be half of the power supply voltage, and the power supply voltage may be one of vdd2h, vdd2l and vdd1 mentioned above, or any combination thereof.

As an example, if the power supply voltage of the DRAM is 1.5V, the first driving voltage vcp is about 0.75V, if the DRAM adopts a higher power supply voltage (for example, 3.3V), the first driving voltage vcp is about 1.65V, and this “half-voltage” design can balance requirements between signal swing, power consumption and reliability, to provide a stable reference voltage for the capacitor.

The memory device 400 further comprises a second driving circuit 408 coupled to the power-on initialization circuit 404 and a word line, respectively, and configured to apply a second driving voltage to the word line in the power-on initialization phase, to cause the transistor coupled to the word line to be turned on. The absolute value of the second driving voltage is greater than the absolute value of the threshold voltage of the transistor, and the second driving voltage will be denoted as vwln_high below. The second driving circuit 408 may be the word line driving circuit shown in FIG. 4B, so as to reuse the word line driving circuit. Of course, in other examples, the second driving circuit 408 may also be a newly added driving circuit.

As an example, if the transistor of the memory cell is an N-channel Metal-Oxide-Semiconductor (NMOS) transistor, the threshold voltage Vth of the NMOS transistor is positive, that is, the second driving voltage vwln_high is greater than the threshold voltage Vth of the NMOS transistor, and if the transistor of the memory cell is a P-channel Metal-Oxide-Semiconductor (PMOS) transistor, the threshold voltage-Vth of the PMOS transistor is negative, that is, the second driving voltage vwln_high is less than the threshold voltage-Vth of the PMOS transistor. Thus, the absolute value of the second driving voltage vwln_high is greater than the absolute value of the threshold voltage of the transistor. For ease of understanding, the following will take the transistor being an NMOS transistor as an example to illustrate.

In an example of the present disclosure, by setting the second driving circuit 408 to apply the second driving voltage vwln_high to the word line in the power-on initialization phase, the transistor coupled to the word line may be turned on, and a memory node may be discharged through the turned-on transistor. In this way, the memory node can be prevented from being coupled to a undetermined voltage level in the power-on initialization phase, so that unbalanced current of a cell board is avoided, and all memory cells can be initialized to a “0” state, that is, the memory cells are in a determined state, thereby ensuring the sensing margin between data “0” and “1” during subsequent read, which is beneficial to improving reliability of data read.

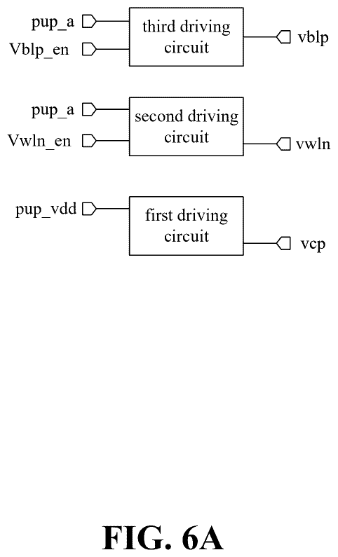

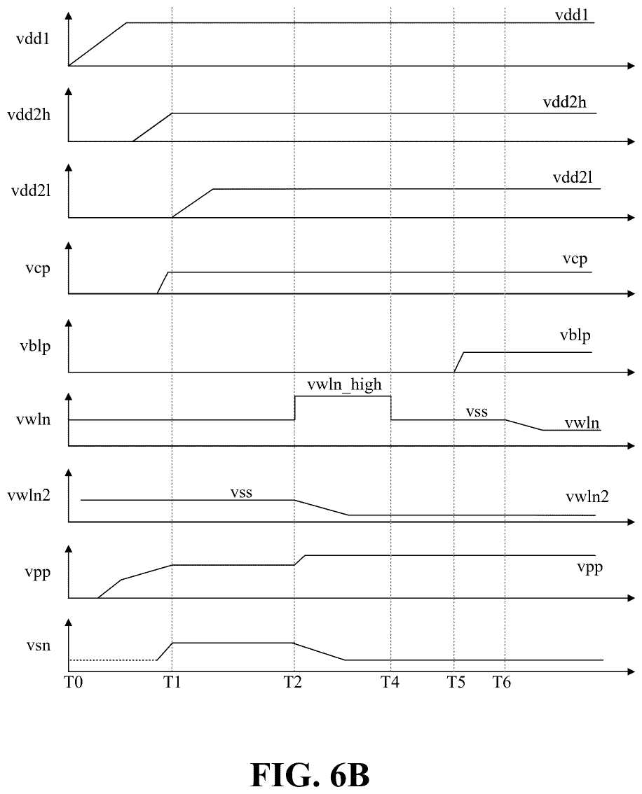

FIG. 6A is a schematic diagram of a peripheral circuit according to a first example of the present disclosure, FIG. 6B is a timing diagram of applying a second driving voltage to a word line according to a first example of the present disclosure, and the first example of the present disclosure will be described by way of example below with reference to FIG. 5, FIG. 6A and FIG. 6B.

In some examples, referring to FIG. 5, FIG. 6A, and FIG. 6B, the power-on initialization circuit 404 is configured to: generate a first control signal pup_vdd at a first time T1 of a power-on initialization phase, generate a power-on completion signal pup_a at a second time T2 of the power-on initialization phase, wherein the second time T2 is later than the first time T1, and the power-on completion signal pup_a indicates that the memory device 400 has completed power-on, the first driving circuit 406 is configured to: apply a first driving voltage vcp to a second terminal based on the first control signal pup_vdd, and the second driving circuit 408 is configured to: apply a second driving voltage vwln_high to a word line at the second time T2.

As an example, the power-on initialization circuit 404 may generate the first control signal pup_vdd at a first time T1 at which a first power supply voltage vdd2h reaches a stable state, and when the first power supply voltage vdd2h reaches the stable state, the first driving circuit 406 may provide a first driving voltage vcp to a cell board, that is, the first driving circuit 406 applies the first driving voltage vcp to a second terminal based on the first control signal pup_vdd.

It should be noted that, at an initial time T0, the memory device 400 starts to be powered on, and at a first time T1, at least part of the power supply voltages (for example, vdd2h and vdd1) reach a stable state, and the power-on initialization circuit 404 starts to perform a reset operation, for example, all memory cells are initialized to a “0” state. The first control signal pup_vdd indicates that the power supply voltage of the first driving circuit 406 reaches the stable state.

As an example, the power-on initialization circuit 404 may generate a power-on completion signal pup_a at a second time T2 at which power-on is completed, and when the power-on is completed, the second driving circuit 408 may provide a second driving voltage vwln_high to a word line, that is, the second driving circuit 408 applies the second driving voltage vwln_high to the word line at the second time T2.

In examples of the present disclosure, by setting the second driving circuit 408 to apply the second driving voltage vwln_high to the word line at the second time T2 at which the power-on is completed, a coupled memory node can be discharged in time through a turned-on transistor, so that initialized memory cells can be prevented from being in an undetermined state, thereby ensuring that all the memory cells after the memory device 400 is powered on are initialized to a “0” state.

In some examples, the power supply voltage of the first driving circuit 406 may be a first power supply voltage vdd2h, and a first driving voltage vcp may be half of the first power supply voltage vdd2h. Of course, in other examples, if the power supply voltage of the first driving circuit 406 is a second power supply voltage vdd2l, a first time T1 may be the time when the second power supply voltage vdd2l reaches a stable state, and the first driving voltage vcp may be half of the second power supply voltage vdd2l.

In some examples, referring to FIG. 5, FIG. 6A, and FIG. 6B, the memory device 400 further comprises a control logic circuit 410 coupled to the power-on initialization circuit 404 and the second driving circuit 408, respectively, and configured to generate a second control signal Vwln_en at a second time T2, the first driving circuit 406 is configured to drive a second terminal to be charged from an initial voltage to a first driving voltage vcp based on a first control signal pup_vdd, wherein a first terminal is coupled to the second terminal being charged, and the second driving circuit 408 is configured to apply a second driving voltage vwln_high to a word line based on the second control signal Vwln_en, wherein the first terminal coupled is discharged through the turned-on transistor.

As an example, the first driving circuit 406 may drive a cell board to be charged from an initial voltage to a first driving voltage vcp based on a first control signal pup_vdd, that is, drive a second terminal to be charged from the initial voltage to the first driving voltage vcp. When the second terminal is charged, the charge in a capacitor changes, so that the voltage of a first electrode plate changes, that is, a first terminal is coupled to the second terminal being charged, and the voltage of the memory node increases accordingly, as shown in FIG. 6B.

As an example, at a second time T2, the memory device 400 has completed power-on, the control logic circuit 410 may generate a second control signal Vwln_en which indicates to select (or drive) a corresponding word line, the second driving circuit 408 may provide a second driving voltage vwln_high to a word line based on the second control signal Vwln_en, to cause a transistor to be turned on, a first terminal coupled may be discharged through the turned-on transistor, and the voltage of a memory node decreases accordingly, as shown in FIG. 6B. In this example, in the process of applying the second driving voltage vwln_high to the word line, a bit line may be coupled to the ground.

It can be understood that, in the process of power-on initialization, a first terminal is coupled to a second terminal being charged, and the voltage of a memory node increases accordingly, which will change the state of a memory cell. In the example of the present disclosure, by generating a second control signal Vwln_en after power-on is completed, the second driving circuit 408 may be controlled to select a corresponding word line, to cause a transistor coupled to a word line to be turned on, the first terminal coupled may be discharged through the turned-on transistor, the voltage of a memory node decreases accordingly, and the memory cell may be restored to be of a “0” state.

In some examples, referring to FIG. 5, FIG. 6A, and FIG. 6B, the second driving circuit 408 is further configured to: stop applying a second driving voltage vwln_high to a word line at a fourth time T4 after a second time T2.

As an example, at a fourth time T4, the voltage on a word line is switched from a high level to a low level, and the transistor coupled to the word line is turned off. In this example, after the voltage of a memory node decreases to 0, the control logic circuit 410 may control the second driving circuit 408 to deselect a corresponding word line, and the second driving circuit 408 no longer provides a second driving voltage vwln_high to the word line, that is, stop applying the second driving voltage vwln_high to the word line.

It should be noted that, the duration during which a second driving voltage vwln_high is applied to a word line (for example, the second time T2 to the fourth time T4 in FIG. 6B) is related to the level to which a first terminal is coupled. If the first terminal is coupled to a higher voltage level, the duration during which the second driving voltage vwln_high is applied to the word line may be controlled to be longer, to ensure that the first terminal coupled is sufficiently discharged, and if the first terminal is coupled to a lower voltage level, the duration during which the second driving voltage vwln_high is applied to the word line may be controlled to be shorter, to save power consumption. In practical applications, the duration can be reasonably set according to actual conditions, which is not particularly limited in the present disclosure.

In some examples, referring to FIG. 5, FIG. 6A and FIG. 6B, the memory device 400 further comprises a third driving circuit 412 coupled to the power-on initialization circuit 404 and bit lines, respectively, and configured to: apply a bit line voltage vblp to a bit line during a sensing phase after a power-on initialization phase, and the second driving circuit 408 is further configured to: apply a word line voltage vwln to a word line in the sensing phase. The third driving circuit 412 may be the bit line driving circuit shown in FIG. 4B, so as to reuse the bit line driving circuit.

As an example, in performing a read operation, the third driving circuit 412 may provide a bit line voltage vblp to a bit line, and the second driving circuit 408 may provide a word line voltage vwln to a word line, so as to select a corresponding memory cell for data read. For example, the sensing amplifier 250 in FIG. 2A senses and amplifies an electrical signal on the bit line, and may read out data stored in the memory cell. In this example, the read operation comprises a sensing phase. Of course, in other examples, the sensing may also be performed in a refresh operation to read out data stored in the memory cell and write back to the memory cell.

In some examples, the third driving circuit 412 is configured to: in a sensing phase, drive a bit line to be charged from an initial bit line voltage to a bit line voltage vblp, and the second driving circuit 408 is configured to: apply a word line voltage vwln to a word line after the bit line is charged to the bit line voltage vblp.

As an example, from a fifth time T5 to a sixth time T6, the third driving circuit 412 may drive a bit line to be charged from an initial bit line voltage to a bit line voltage vblp based on a third control signal Vblp_en, and at the sixth time T6, the second driving circuit 408 provides a word line voltage vwln to a word line. Here, the initial bit line voltage may be the ground voltage vss, and the absolute value of the word line voltage vwln is greater than the absolute value of the threshold voltage of a transistor.

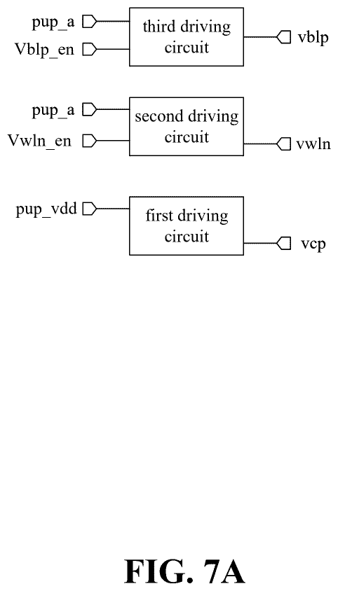

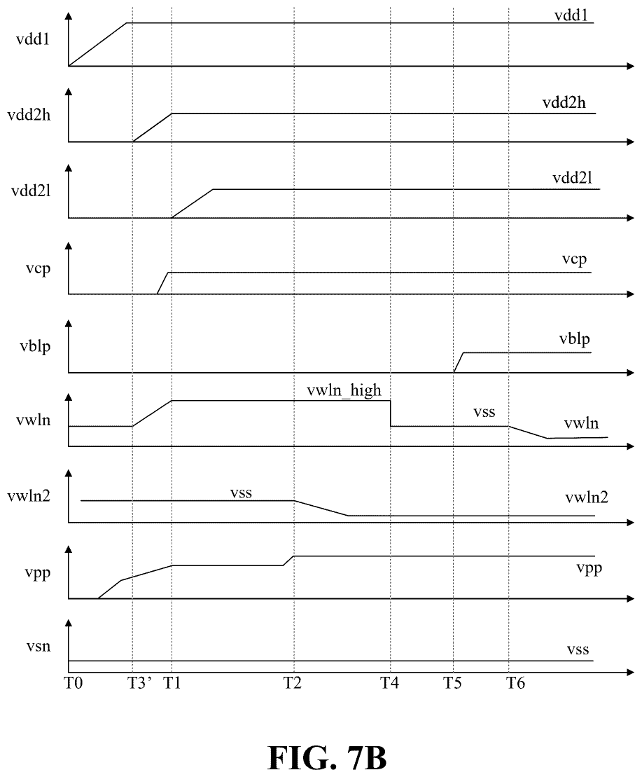

FIG. 7A is a schematic diagram of a peripheral circuit according to a second example of the present disclosure, FIG. 7B is a timing diagram of applying a second driving voltage to a word line according to a second example of the present disclosure, and the second example of the present disclosure will be described by way of example below with reference to FIG. 5, FIG. 7A and FIG. 7B.

In some examples, referring to FIG. 5, FIG. 7A and FIG. 7B, the second driving circuit 408 is configured to: apply a second driving voltage vwln_high to a word line at a third time T3′ before a first time T1.

As an example, at a third time T3′ after an initial time T0, a third power supply voltage vdd1 reaches a stable state, and when a third power supply voltage vdd1 reaches a stable state, the second driving circuit 408 may provide a second driving voltage vwln_high to a word line, that is, the second driving circuit 408 applies the second driving voltage vwln_high to the word line at the third time T3′.

In examples of the present disclosure, by setting the second driving circuit 408 to apply the second driving voltage vwln_high to the word line at the third time T3′ before the first time T1, a transistor may be turned on before a memory node is coupled, even ramp-up of the voltage of a cell board between the third time T3′ and the first time T1 is difficult to couple the memory node, so that initialized memory cells can be prevented from being in an undetermined state, thereby ensuring that all the memory cells after power-on of the memory device 400 are initialized to a “0” state. Here, the voltage of the cell board ramps up to a first driving voltage vcp at the first time T1.

In some examples, the supply voltage of the second driving circuit 408 may be a third power supply voltage vdd1, and a second driving voltage vwln_high is less than or equal to the third power supply voltage vdd1. Of course, in other examples, if the supply voltage of the second driving circuit 408 is a first power supply voltage vdd2h, a third time T3′ and a first time T1 may be the same time, and the second driving voltage vwln_high is less than or equal to the first power supply voltage vdd2h.

In some examples, the memory device 400 further comprises the control logic circuit 410 coupled to the power-on initialization circuit 404 and the second driving circuit 408, respectively, and configured to: generate a second control signal Vwln_en at a third time T3′, and the second driving circuit 408 is configured to: apply a second driving voltage vwln_high to a word line based on the second control signal Vwln_en.

In examples of the present disclosure, the control logic circuit 410 may generate a second control signal Vwln_en at a third time T3′, so as to control the second driving circuit 408 to provide a second driving voltage vwln_high to a word line, to cause a transistor to be turned on. A second terminal starts to be charged after the third time T3′, and reaches a stable state at a first time T1, and in the process of charging the second terminal, since the transistor is in the turn-on state, a first terminal can be grounded through the turned-on transistor, so that the first terminal is difficult to be coupled, and the voltage of a memory node is unchanged, as shown in FIG. 7B.

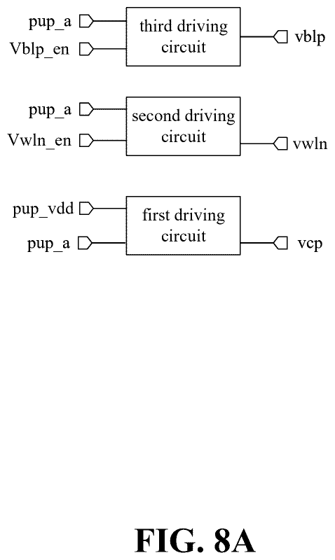

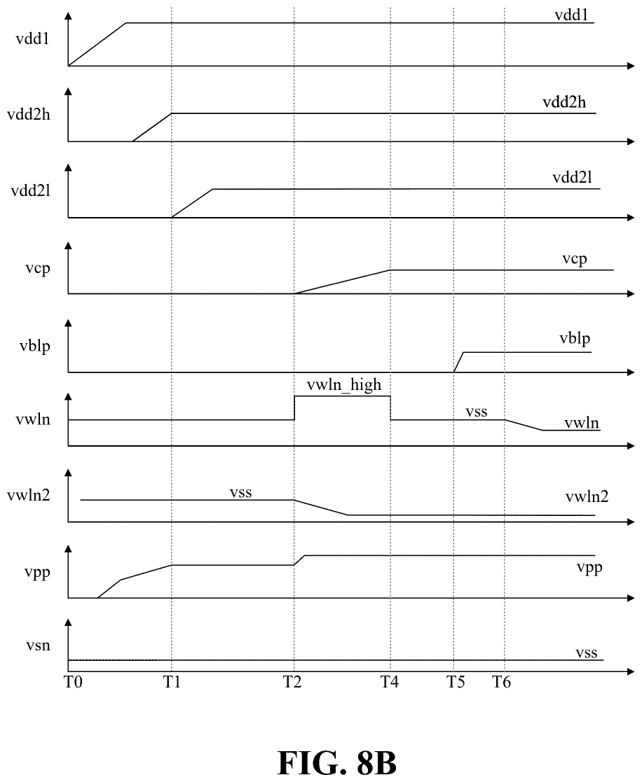

FIG. 8A is a schematic diagram of a peripheral circuit according to a third example of the present disclosure, FIG. 8B is a timing diagram of applying a second driving voltage to a word line according to a third example of the present disclosure, and the third example of the present disclosure will be described by way of example below with reference to FIG. 5, FIG. 8A and FIG. 8B.

In some examples, referring to FIG. 5, FIG. 8A, and FIG. 8B, the power-on initialization circuit 404 is configured to: generate a power-on completion signal pup_a at a second time T2 of a power-on initialization phase, wherein the power-on completion signal pup_a indicates that the memory device 400 has completed power-on, the first driving circuit 406 is configured to: apply a first driving voltage vcp to a second terminal based on the power-on completion signal pup_a, and the second driving circuit 408 is configured to: apply a second driving voltage vwln_high to the word line at the second time T2.

In examples of the present disclosure, at the second time T2, the first driving circuit 406 provides the first driving voltage vcp to a cell board, and the second driving circuit 408 provides the second driving voltage vwln_high to the word line, that is, in the process of charging the second terminal, a transistor is kept to be in a turn-on state, a first terminal can be grounded through the turned-on transistor, so that the first terminal is difficult to be coupled, and the voltage of a memory node is unchanged, as shown in FIG. 8B.

In some examples, the memory device 400 further comprises a control logic circuit 410 coupled to the power-on initialization circuit 404 and the second driving circuit 408, respectively, and configured to: generate a second control signal Vwln_en at the second time T2, the second driving circuit 408 is configured to: apply the second driving voltage vwln_high to the word line based on the second control signal Vwln_en.

As an example, at the second time T2, the control logic circuit 410 may generate the second control signal Vwln_en, so as to control the second driving circuit 408 to provide the second driving voltage vwln_high to the word line, to cause the transistor to be turned on, even if the second terminal is charged at the second time T2, the first terminal is difficult to be coupled, and the voltage of the memory node is unchanged.

Examples of the present disclosure provides a memory device, comprising: a memory cell, a power-on initialization circuit, a first driving circuit, and a second driving circuit, wherein the memory cell comprises a capacitor and a transistor, the transistor is coupled to a first terminal of the capacitor, the power-on initialization circuit is coupled to the memory cell and is configured to: perform power-on initialization on the memory cell based on the memory device being powered on, the first driving circuit is coupled to the power-on initialization circuit and a second terminal of the capacitor, respectively, and is configured to: apply a first driving voltage to the second terminal in a power-on initialization phase, the second driving circuit is coupled to the power-on initialization circuit and a word line, respectively, and is configured to: apply a second driving voltage to the word line in the power-on initialization phase, to cause the transistor coupled to the word line to be turned on. In this way, in a first aspect, it can be avoided that the memory node is coupled to an undetermined voltage level in the power-on initialization phase, so that unbalanced current of the cell board is avoided, and all memory cells can be initialized to a “0” state, that is, the memory cells are in a determined state, thereby ensuring the sensing margin between data “0” and “1” during subsequent read, which is beneficial to improving reliability of data read; in a second aspect, by providing a new timing of power-on, it may be helpful to set an initial state of the memory cell to a “0” state; in a third aspect, the initialization of the memory cell is performed through a new timing of power-on, and no additional operation is required to be added to the memory cell during power-on initialization; and in a fourth aspect, undetermined leakage current before power-on can be avoided.

Based on the above memory device, examples of the present disclosure provide an operating method of a memory device.

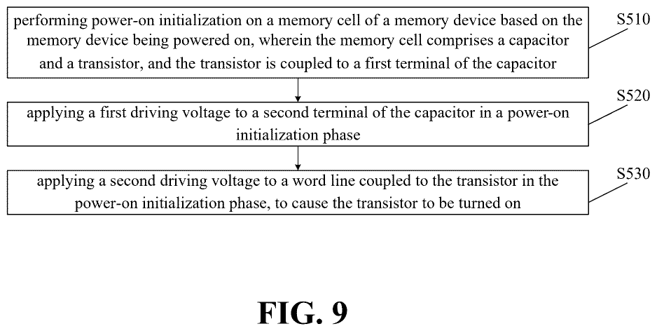

FIG. 9 is a schematic flowchart of an operating method of a memory device according to an example of the present disclosure. It should be noted that, operations shown in FIG. 9 are not exclusive, and other operations may be performed before, after, or between any operations in the illustrated operations, the operations shown in FIG. 9 may be sequentially adjusted according to actual needs. Referring to FIG. 9, the operating method comprises at least the following:

S510: performing power-on initialization on a memory cell of the memory device based on the memory device being powered on, wherein the memory cell comprises a capacitor and a transistor, and the transistor is coupled to a first terminal of the capacitor;

S520: applying a first driving voltage to a second terminal of the capacitor in a power-on initialization phase; and

S530: applying a second driving voltage to a word line coupled to the transistor in the power-on initialization phase, to cause the transistor to be turned on.

In some examples, operation S510 comprises: generating a first control signal at a first time in the power-on initialization phase; generating a power-on completion signal at a second time in the power-on initialization phase, wherein the second time is later than the first time, and the power-on completion signal indicates that the memory device has completed power-on, and operation S520 comprises: applying the first driving voltage to the second terminal based on the first control signal, and operation S530 comprises: applying the second driving voltage to the word line at the second time or a third time before the first time.

In some examples, the operating method further comprises: generating a second control signal at the second time; the applying of the first driving voltage to the second terminal based on the first control signal comprises: driving the second terminal to be charged from an initial voltage to the first driving voltage based on the first control signal, wherein the first terminal is coupled to the second terminal being charged; and the applying of the second driving voltage to the word line at the second time comprises: applying the second driving voltage to the word line based on the second control signal, wherein the first terminal coupled is discharged through the turned-on transistor.

In some examples, the operating method further comprises: generating the second control signal at the third time; and the applying of the second driving voltage to the word line at the second time comprises: applying the second driving voltage to the word line based on the second control signal.

In some examples, operation S510 comprises: generating a power-on completion signal at a second time in the power-on initialization phase, wherein the power-on completion signal indicates that the memory device has completed power-on, and operation S520 comprises: applying the first driving voltage to the second terminal based on the power-on completion signal, and operation S530 comprises: applying the second driving voltage to the word line at the second time.

In some examples, the operating method further comprises: generating the second control signal at the second time; and the applying of the second driving voltage to the word line at the second time comprises: applying the second driving voltage to the word line based on the second control signal.

In some examples, the operating method further comprises: stopping applying the second driving voltage to the word line at a fourth time after the second time.

In some examples, the operating method further comprises: applying a bit line voltage to a bit line coupled to the transistor in a sensing phase after the power-on initialization phase; and applying a word line voltage to the word line in the sensing phase.

In some examples, the applying of the bit line voltage to the bit line coupled to the transistor in the sensing phase after the power-on initialization phase comprises: driving the bit line to be charged from an initial bit line voltage to the bit line voltage in the sensing phase; and the applying of the word line voltage to the word line in the sensing phase comprises: applying the word line voltage to the word line after the bit line is charged to the bit line voltage.

In examples of the present disclosure, the operating method of the memory device may be performed by the memory device in any one of the foregoing examples, and technical effects of the memory device in the foregoing examples may also be implemented, and details are not described herein again. Implementations of operations in the operating method in the above examples are described in detail in examples of a related memory device, and will not be described in detail here.

Based on the above memory device, an example of the present disclosure provides a memory system. The memory system comprises the memory device of any of the above examples and a controller coupled to the memory device. For the memory system and the controller, refer to related descriptions of the memory system 30 and the controller 10 in FIG. 1, respectively.

The features disclosed in the several apparatus examples provided by the present disclosure may be arbitrarily combined without conflict to obtain a new apparatus example.

The method disclosed in the several method examples provided by the present disclosure may be arbitrarily combined without conflict to obtain a new method example.

It should be understood that, “one example” or “an example” mentioned throughout the specification means that a specific feature, structure, or characteristic related to an example is included in at least one example of the present disclosure. Thus, “in one example” or “in an example” appearing throughout the specification need not necessarily refer to the same example. Further, these particular features, structures, or characteristics may be incorporated in one or more examples in any suitable manner. It should be understood that, in various examples of the present disclosure, the sequence numbers of the foregoing processes do not mean a sequence of execution sequences, and an execution sequence of each process should be determined by function and intrinsic logic thereof, and should not constitute any limitation on an example process of examples of the present disclosure. The foregoing sequence numbers of examples of the present disclosure are merely for description, and do not represent the advantages or disadvantages of examples.

It should be noted that, in this specification, the terms “comprising”, “including”, or any other variant thereof are intended to cover a non-exclusive inclusion, such that a process, method, article, or apparatus that comprises a series of elements comprises not only those elements but also other elements not explicitly listed, or elements inherent to such processes, methods, articles, or apparatuses. Without further restriction, the elements defined by the statement “comprise one . . . ” do not preclude the presence of additional identical elements in the process, method, article, or apparatus that comprises the element.

According to a first aspect of the examples of the present disclosure, a memory device is provided, comprising: a memory cell, a power-on initialization circuit, a first driving circuit, and a second driving circuit, wherein the memory cell comprises a capacitor and a transistor, the transistor is coupled to a first terminal of the capacitor, the power-on initialization circuit is coupled to the memory cell and is configured to: perform power-on initialization on the memory cell based on the memory device being powered on, the first driving circuit is coupled to the power-on initialization circuit and a second terminal of the capacitor, respectively, and is configured to: apply a first driving voltage to the second terminal in a power-on initialization phase, the second driving circuit is coupled to the power-on initialization circuit and a word line, respectively, and is configured to: apply a second driving voltage to the word line in the power-on initialization phase, to cause the transistor coupled to the word line to be turned on.

In some examples, the power-on initialization circuit is configured to: generate a first control signal at a first time in the power-on initialization phase; generate a power-on completion signal at a second time in the power-on initialization phase, wherein the second time is later than the first time, and the power-on completion signal indicates that the memory device has completed power-on, the first driving circuit is configured to: apply the first driving voltage to the second terminal based on the first control signal, and the second driving circuit is configured to: apply the second driving voltage to the word line at a third time before the second time or the first time.

In some examples, the memory device further comprises a control logic circuit coupled to the power-on initialization circuit and the second driving circuit, respectively, the control logic circuit is configured to: generate a second control signal at the second time, the first driving circuit is configured to: drive the second terminal to be charged from an initial voltage to the first driving voltage based on the first control signal, wherein the first terminal is coupled to the second terminal being charged, and the second driving circuit is configured to: apply the second driving voltage to the word line based on the second control signal, wherein the first terminal coupled is discharged through the turned-on transistor.

In some examples, the memory device further comprises a control logic circuit coupled to the power-on initialization circuit and the second driving circuit, respectively, the control logic circuit is configured to generate a second control signal at the third time, and the second driving circuit is configured to: apply the second driving voltage to the word line based on the second control signal.

In some examples, the power-on initialization circuit is configured to: generate a power-on completion signal at a second time in the power-on initialization phase, wherein the power-on completion signal indicates that the memory device has completed power-on, the first driving circuit is configured to: apply the first driving voltage to the second terminal based on the power-on completion signal, and the second driving circuit is configured to: apply the second driving voltage to the word line at the second time.

In some examples, the memory device further comprises a control logic circuit coupled to the power-on initialization circuit and the second driving circuit, respectively, the control logic circuit is configured to: generate a second control signal at the second time, and the second driving circuit is configured to: apply the second driving voltage to the word line based on the second control signal.

In some examples, the second driving circuit is further configured to: stop applying the second driving voltage to the word line at a fourth time after the second time.

In some examples, the memory device further comprises a third driving circuit coupled to the power-on initialization circuit and a bit line, respectively, the third driving circuit is configured to: apply a bit line voltage to the bit line in a sensing phase after the power-on initialization phase, and the second driving circuit is further configured to: apply a word line voltage to the word line in the sensing phase.

In some examples, the third driving circuit is configured to: drive the bit line to be charged from an initial bit line voltage to the bit line voltage in the sensing phase, and the second driving circuit is configured to: after the bit line is charged to the bit line voltage, apply the word line voltage to the word line.

In some examples, the memory device comprises a dynamic random access memory.

According to a second aspect of the examples of the present disclosure, an operating method of a memory device is provided, comprising: performing power-on initialization on a memory cell of the memory device based on the memory device being powered on, wherein the memory cell comprises a capacitor and a transistor, and the transistor is coupled to a first terminal of the capacitor; applying a first driving voltage to a second terminal of the capacitor in a power-on initialization phase; and applying a second driving voltage to a word line coupled to the transistor in the power-on initialization phase, to cause the transistor to be turned on.

In some examples, the performing of the power-on initialization on the memory cell of the memory device based on the memory device being powered on comprises: generating a first control signal at a first time in the power-on initialization phase; generating a power-on completion signal at a second time in the power-on initialization phase, wherein the second time is later than the first time, and the power-on completion signal indicates that the memory device has completed power-on, the applying of the first driving voltage to the second terminal of the capacitor in the power-on initialization phase comprises: applying the first driving voltage to the second terminal based on the first control signal, and the applying of the second driving voltage to the word line coupled to the transistor in the power-on initialization phase comprises: applying the second driving voltage to the word line at a third time before the second time or the first time.

In some examples, the operating method further comprises: generating a second control signal at the second time, the applying of the first driving voltage to the second terminal based on the first control signal comprises: driving the second terminal to be charged from an initial voltage to the first driving voltage based on the first control signal, wherein the first terminal is coupled to the second terminal being charged, and the applying of the second driving voltage to the word line at the second time comprises: applying the second driving voltage to the word line based on the second control signal, wherein the first terminal coupled is discharged through the turned-on transistor.

In some examples, the operating method further comprises: generating a second control signal at the third time, and the applying of the second driving voltage to the word line at the second time comprises: applying the second driving voltage to the word line based on the second control signal.

In some examples, the performing power-on initialization on the memory cell of the memory device based on the memory device being powered on comprises: generating a power-on completion signal at a second time in the power-on initialization phase, wherein the power-on completion signal indicates that the memory device has completed power-on, the applying of the first driving voltage to the second terminal in the power-on initialization phase comprises: applying the first driving voltage to the second terminal based on the power-on completion signal, and the applying of the second driving voltage to the word line coupled to the transistor in the power-on initialization phase comprises: applying the second driving voltage to the word line at the second time.

In some examples, the operating method further comprises: generating a second control signal at the second time, and the applying of the second driving voltage to the word line at the second time comprises: applying the second driving voltage to the word line based on the second control signal.

In some examples, the operating method further comprises: stopping applying the second driving voltage to the word line at a fourth time after the second time.

In some examples, the operating method further comprises: applying a bit line voltage to a bit line coupled to the transistor in a sensing phase after the power-on initialization phase; and applying a word line voltage to the word line in the sensing phase.

In some examples, the applying of the bit line voltage to the bit line coupled to the transistor in the sensing phase after the power-on initialization phase comprises: driving the bit line to be charged from an initial bit line voltage to the bit line voltage in the sensing phase, and the applying of the word line voltage to the word line in the sensing phase comprises: applying the word line voltage to the word line after the bit line is charged to the bit line voltage.

According to a third aspect of examples of the present disclosure, a memory system is provided, comprising the memory device according to any one of the first aspect of the examples of the present disclosure and a controller coupled to the memory device.

In examples of the present disclosure, by setting the second driving circuit to apply the second driving voltage to the word line in the power-on initialization phase, the transistor coupled to the word line may be turned on, and a memory node may be discharged through the turned-on transistor. In this way, the memory node can be prevented from being coupled to an undetermined voltage level in the power-on initialization phase, so that unbalanced current of a cell board is avoided, and all memory cells can be initialized to a “0” state, that is, the memory cells are in a determined state, thereby ensuring the sensing margin between data “0” and “1” during subsequent read, which is beneficial to improving reliability of data read.

The above description is only an example of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A memory device comprising:
a memory cell comprising a capacitor and a transistor, wherein the transistor is coupled to a first terminal of the capacitor;
a power-on initialization circuit coupled to the memory cell and configured to perform power-on initialization on the memory cell based on the memory device being powered on;
a first driving circuit coupled to the power-on initialization circuit and a second terminal of the capacitor, respectively, and configured to apply a first driving voltage to the second terminal during a power-on initialization phase; and
a second driving circuit coupled to the power-on initialization circuit and a word line, respectively, and configured to apply a second driving voltage to the word line during the power-on initialization phase to cause the transistor coupled to the word line to be turned on.

2. The memory device of claim 1, wherein:
the power-on initialization circuit is configured to:
generate a first control signal at a first time during the power-on initialization phase; and
generate a power-on completion signal at a second time during the power-on initialization phase, wherein the second time is later than the first time, and the power-on completion signal indicates that the memory device has completed power-on;
the first driving circuit is configured to apply the first driving voltage to the second terminal based on the first control signal; and
the second driving circuit is configured to apply the second driving voltage to the word line at the second time or a third time before the first time.

3. The memory device of claim 2, further comprising a control logic circuit coupled to the power-on initialization circuit and the second driving circuit, respectively, wherein:
the control logic circuit is configured to generate a second control signal at the second time;
the first driving circuit is configured to drive the second terminal to be charged from an initial voltage to the first driving voltage based on the first control signal, wherein the first terminal is coupled to the second terminal being charged; and
the second driving circuit is configured to apply the second driving voltage to the word line based on the second control signal, wherein the first terminal is discharged through the turned-on transistor.

4. The memory device of claim 2, further comprising a control logic circuit coupled to the power-on initialization circuit and the second driving circuit, respectively, wherein:
the control logic circuit is configured to generate a second control signal at the third time; and
the second driving circuit is configured to apply the second driving voltage to the word line based on the second control signal.

5. The memory device of claim 1, wherein:
the power-on initialization circuit is configured to generate a power-on completion signal at a second time during the power-on initialization phase, wherein the power-on completion signal indicates that the memory device has completed power-on;
the first driving circuit is configured to apply the first driving voltage to the second terminal based on the power-on completion signal; and
the second driving circuit is configured to apply the second driving voltage to the word line at the second time.

6. The memory device of claim 5, further comprising a control logic circuit coupled to the power-on initialization circuit and the second driving circuit, respectively, wherein:
the control logic circuit is configured to generate a second control signal at the second time; and
the second driving circuit is configured to apply the second driving voltage to the word line based on the second control signal.

7. The memory device of claim 2, wherein the second driving circuit is configured to stop applying the second driving voltage to the word line at a fourth time after the second time.

8. The memory device of claim 1, further comprising a third driving circuit coupled to the power-on initialization circuit and a bit line, respectively, wherein:
the third driving circuit is configured to apply a bit line voltage to the bit line during a sensing phase after the power-on initialization phase; and
the second driving circuit is further configured to apply a word line voltage to the word line during the sensing phase.

9. The memory device of claim 8, wherein:
the third driving circuit is configured to drive the bit line to be charged from an initial bit line voltage to the bit line voltage during the sensing phase; and
the second driving circuit is configured to, after the bit line is charged to the bit line voltage, apply the word line voltage to the word line.

10. The memory device of claim 1, wherein the memory device comprises a dynamic random access memory.

11. A method of a memory device, the method comprising:
performing power-on initialization on a memory cell of the memory device based on the memory device being powered on, wherein the memory cell comprises a capacitor and a transistor, and the transistor is coupled to a first terminal of the capacitor;
applying a first driving voltage to a second terminal of the capacitor during a power-on initialization phase; and
during the power-on initialization phase, applying a second driving voltage to a word line coupled to the transistor to cause the transistor to be turned on.

12. The method of claim 11, wherein:
the performing of the power-on initialization on the memory cell of the memory device based on the memory device being powered on comprises:
generating a first control signal at a first time during the power-on initialization phase; and
generating a power-on completion signal at a second time during the power-on initialization phase, wherein the second time is later than the first time, and the power-on completion signal indicates that the memory device has completed power-on;
the applying of the first driving voltage to the second terminal of the capacitor during the power-on initialization phase comprises applying the first driving voltage to the second terminal based on the first control signal; and
the applying of the second driving voltage to the word line coupled to the transistor comprises applying the second driving voltage to the word line at the second time or a third time before the first time.

13. The method of claim 12, further comprising generating a second control signal at the second time, wherein:
the applying of the first driving voltage to the second terminal based on the first control signal comprises driving the second terminal to be charged from an initial voltage to the first driving voltage based on the first control signal, wherein the first terminal is coupled to the second terminal being charged; and
the applying of the second driving voltage to the word line at the second time comprises applying the second driving voltage to the word line based on the second control signal, wherein the first terminal is discharged through the turned-on transistor.

14. The method of claim 12, further comprising generating a second control signal at the third time, wherein:
the applying of the second driving voltage to the word line at the second time comprises applying the second driving voltage to the word line based on the second control signal.

15. The method of claim 11, wherein the performing of the power-on initialization on the memory cell of the memory device based on the memory device being powered on comprises:
generating a power-on completion signal at a second time during the power-on initialization phase, wherein the power-on completion signal indicates that the memory device has completed power-on;
the applying of the first driving voltage to the second terminal during the power-on initialization phase comprises applying the first driving voltage to the second terminal based on the power-on completion signal; and
the applying of the second driving voltage to the word line coupled to the transistor comprises applying the second driving voltage to the word line at the second time.

16. The method of claim 15, further comprising generating a second control signal at the second time, wherein:
the applying of the second driving voltage to the word line at the second time comprises applying the second driving voltage to the word line based on the second control signal.

17. The method of claim 12, further comprising stopping the applying of the second driving voltage to the word line at a fourth time after the second time.

18. The method of claim 11, further comprising:
during a sensing phase after the power-on initialization phase, applying a bit line voltage to a bit line coupled to the transistor; and
applying a word line voltage to the word line during the sensing phase.

19. The method of claim 18, wherein:
the applying of the bit line voltage to the bit line coupled to the transistor comprises driving the bit line to be charged from an initial bit line voltage to the bit line voltage during the sensing phase; and
the applying of the word line voltage to the word line during the sensing phase comprises applying the word line voltage to the word line after the bit line is charged to the bit line voltage.

20. A memory system comprising:
a memory device comprising:
a memory cell comprising a capacitor and a transistor, wherein the transistor is coupled to a first terminal of the capacitor;
a power-on initialization circuit coupled to the memory cell and configured to perform power-on initialization on the memory cell based on the memory device being powered on;
a first driving circuit coupled to the power-on initialization circuit and a second terminal of the capacitor, respectively, and configured to apply a first driving voltage to the second terminal during a power-on initialization phase;
and a second driving circuit coupled to the power-on initialization circuit and a word line, respectively, and configured to, during the power-on initialization phase, apply a second driving voltage to the word line to cause the transistor coupled to the word line to be turned on; and
a controller coupled to the memory device.
